(19) United States
(12) Patent Application Publication
(10) Pub. No.: US 2024/0126932 A1
(43) Pub. Date: Apr. 18, 2024

(54) DESIGN SUPPORT DEVICE, METHOD, AND PROGRAM

(71) Applicant: Hitachi, Ltd., Tokyo (JP)

(72) Inventor: Ichiro KATAOKA, Tokyo (JP)

(73) Assignee: Hitachi, Ltd., Tokyo (JP)

(21) Appl. No.: 18/278,088

(22) PCT Filed: Feb. 2, 2022
(86) PCT No.: PCT/JP2022/004129

§ 371 Date: Aug. 21, 2023

(30) Foreign Application Priority Data
Mar. 16, 2021 (JP) 2021-041925

(51) Int. Cl. G06F 30/10

(52) U.S. Cl. CPC G06F 30/10

(57) ABSTRACT

A design support device for performing a check of a defect suppresses defects such as rework in product design and manufacturing and appropriately proposing a criterion, which is an item to be checked in accordance with the actual situation. The design support device includes a memory that stores past subject information for a product designed in the past, thereby storing a correspondence table in which criteria indicating check items are associated, an input unit that receives input of new subject information of a product of a new subject to be checked, a priority calculation unit that calculates a priority of the criterion indicating the check item for the product of the new subject corresponding to the input new subject information, using the correspondence table, and an output unit that outputs the calculated criterion on the screen according to the priority.

### TECHNICAL FIELD

The present invention relates to a technique for supporting the design of an object (hereinafter referred to as a product) such as a product, a part, an apparatus, and a system. Among them, the present invention particularly relates to checking a defect related to design. The defect indicates a factor that requires an additional process such as rework in processes such as design, manufacturing, and delivery.

### BACKGROUND ART

In product design, it is widely practiced to examine and create a shape using a drawing called CAD and a three-dimensional CAD and evaluate product quality. In shape creation using the drawing and the three-dimensional CAD, manufacturability is checked at a design stage to see if a designed shape can actually be subjected to processing work and assembly work. By checking the manufacturability at the design stage, it is possible to prevent rework in a post-process and defective design.

For example, in the system described in PTL 1, a method of checking a design rule when creating a three-dimensional CAD shape and checking workability at the design stage is disclosed. It is important to program information on a design criterion and a restriction on a processing machine so that workability of a shape can be checked in advance.

On the other hand, although it is desirable to program defect information so as to be able to be checked at the design stage so that a defect will not reoccur if the defect occurs, it is only possible to reflect the defect information or the like in a design checklist and check it without considering a priority of the criteria to be checked for a subject.

For example, the systems described in PTL 2 and PTL 3 disclose a method of reducing the occurrence of defective design by associating past design change with defect information and providing them to a designer's terminal.

Further, the system described in PTL 4 discloses a method of supporting design and production management by searching for past similar CADs and describing necessary information in an important portion when design change is made.

### CITATION LIST

### Patent Literature

PTL 1: JP2010-211434A
PTL 2: JP2010-9151A
PTL 3: JPH08-30670A
PTL 4: JP2013-97743A

### SUMMARY OF INVENTION

### Technical Problem

In order to check the contents corresponding to the defect at the design stage, it is necessary not only to perform check by referring to the design checklist, but also to check the shape on the drawing and 3D CAD. In the techniques described in PTLs 1 to 3 above, a method of performing a design check while presenting defect information is proposed. However, since an item to be checked for a customer's request and the shape change and a criterion to be checked corresponding to the item also changes, it is desirable to be able to check a design deliverable from important points. Further, in the technique described in PTL 4, although a method of adding information to an important portion by referring to a past similar CAD has been proposed, there is no description about adding or checking information in consideration of a priority of information.

Since there are multiple criteria and items to be checked when examining a product configuration for the customer's request without being limited to CAD, checking an item to be examined with priority first leads to efficient development. A problem to be solved by the present invention is to suppress the defect in product design and to appropriately propose a criterion, which is an item to be checked in accordance with the actual condition.

### Solution to Problem

A configuration of the present invention for solving the problems described above is a design support device for performing a check of a defect in design, the design support device including a storage unit that stores a correspondence table in which past subject information for a product designed in the past is associated with a criterion indicating a check item, an input unit that receives input of new subject information of a product of a new subject to be checked, a priority calculation unit that calculates a priority of the criterion indicating the check item for the product of the new subject corresponding to the input new subject information, using the correspondence table, and an output unit that outputs the calculated criterion according to the priority.

Further, the present invention includes a design support method using the design support device and a program for causing the design support device to function as a computer.

### Advantageous Effects of Invention

According to the present invention, it is possible to present a criterion indicating a check item with priority in accordance with the actual situation, improve design efficiency, and avoid a risk at the design stage.

### BRIEF DESCRIPTION OF DRAWINGS

FIG. 1 is a diagram illustrating a configuration of a design support device according to an embodiment of the present invention.

FIG. 2 is a diagram illustrating past subject information used in an embodiment of the present invention.

FIG. 3 is a diagram illustrating processing by the design support device according to an embodiment of the present invention.

FIGS. 4A and 4B are diagrams illustrating an example of processing for extracting a feature amount according to an embodiment of the present invention.

FIG. 5 is a diagram illustrating a correspondence table used in an embodiment of the present invention.

FIG. 6 is a diagram illustrating an example of priority calculation according to an embodiment of the present invention.

FIG. 7 is a diagram illustrating display contents of a screen according to an embodiment of the present invention.

### DESCRIPTION OF EMBODIMENTS

Hereinafter, an embodiment of the present invention will be described with reference to the drawings. In this embodiment, an example of checking a defect in product design will be described. As a premise for this, it is assumed that a product has been designed several times and information (past subject information) at that time is managed.

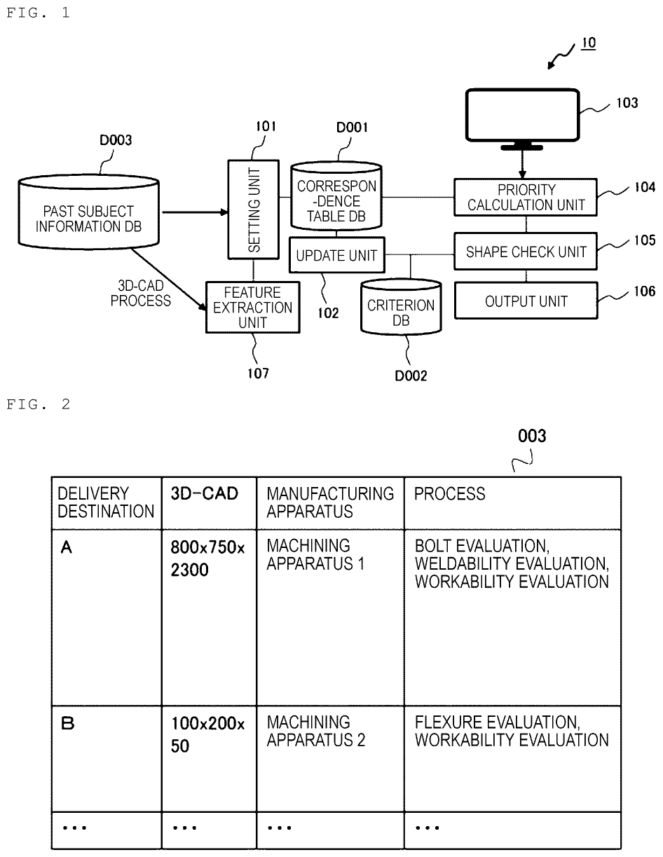

First, using FIG. 1, a configuration diagram of an example of a design support device 10 according to this embodiment will be described. The design support device 10 is realized by a computing machine (computer), and includes a correspondence table DB D001, a criterion DB D002, a past subject information DB D003, a setting unit 101, an update unit 102, a screen 103, a priority calculation unit 104, a shape check unit 105, an output unit 106, and a feature extraction unit 107. This computer may be realized as a so-called cloud system (server) or as a stand-alone computer. In the former case, the screen 103 is desirably provided on a terminal device connected to the server. Further, a storage unit that realizes each DB may also be provided on a network connected to the design support device 10.

Here, the setting unit 101, the update unit 102, the priority calculation unit 104, the shape check unit 105, the output unit 106, and the feature extraction unit 107 are desirably realized by a computer program and a processing unit that processes according to the program, but the units may be realized by dedicated hardware. Further, the computer program can be distributed by being distributed via a network or stored in a storage medium.

Furthermore, the correspondence table DB D001, the criterion DB D002, and the past subject information DB D003 can be realized by a storage unit called storage. Furthermore, although not illustrated, the design support device 10 includes an input unit that receives various types of information.

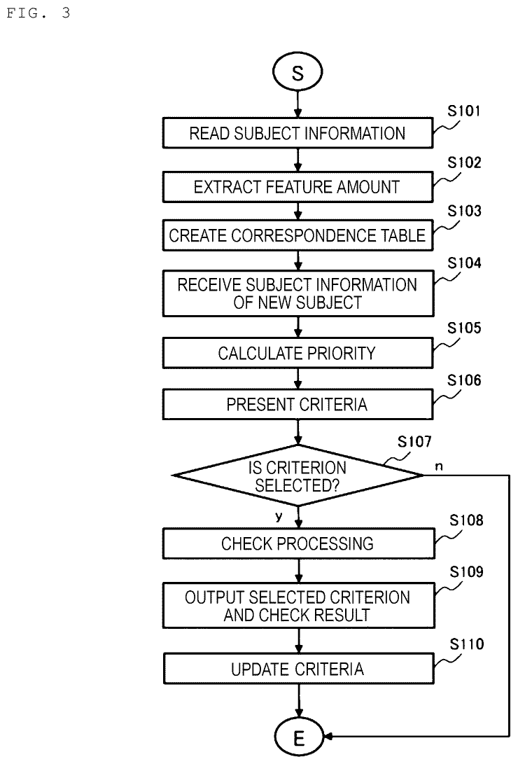

Each configuration will be described below. The setting unit 101 uses past subject information 003 stored in the past subject information DB D003 to create a correspondence table 001 for specifying a criterion, which is a check item. The past subject information includes a delivery destination, design information, a process indicating a check item, a manufacturing apparatus used in manufacturing a past subject, and the like in a past subject. In other words, the past subject information is information about subjects including design and manufacturing of the product designed in the past. Here, the past subject information 003 used in this embodiment is illustrated in FIG. 2. The past subject information 003 of this embodiment includes a delivery destination, 3D-CAD which is design information, and a process. Here, the delivery destination indicates a delivery destination of a designed product. The 3D-CAD is design information, and its dimensions are illustrated in FIG. 2 in this embodiment. The process is information indicating a check procedure to be performed.

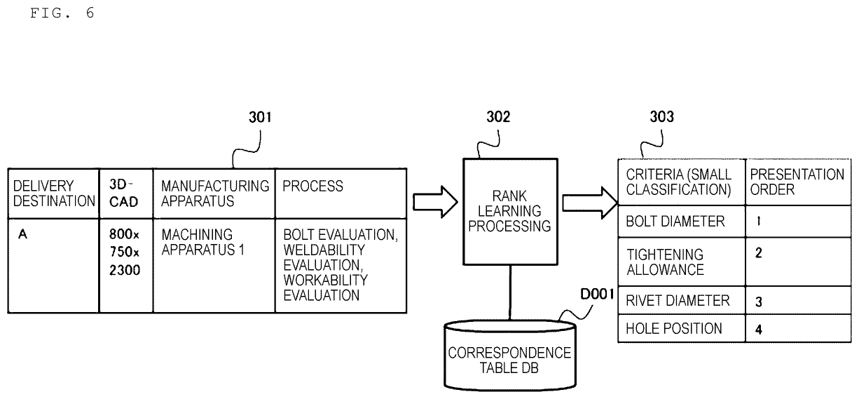

Further, the setting unit 101 also uses a feature amount, which will be described later, for creating the correspondence table 001. In this embodiment, a configuration in which the correspondence table 001 is created is adopted, but the correspondence table 001 may be created in advance. Further, the correspondence table DB D001 stores the correspondence table 001. The correspondence table 001 will be described later using FIG. 5.

Further, the update unit 102 updates a priority of the criterion in the correspondence table 001 based on a check result of a new subject. Further, the screen 103 displays various types of information, and new subject information, which is subject information of the new subject, is received via the input unit using display thereon. Here, the new subject is a subject to be checked. For this reason, the past subject may be subject to check by reviewing the criterion and the like.

Further, the priority calculation unit 104 calculates the priority of the criterion using the new subject information received by the input unit. Further, the shape check unit 105 executes a check whether or not there is a defect in the product of the new subject by using the criterion specified based on the priority. In this case, the shape check unit 105 reads the criterion specified based on the priority from the criterion DB D002, applies the criterion, and checks whether the defect is included in subject information including design contents. Then, the shape check unit 105 presents a checked result on the screen 103 using the output unit 106.

Further, the feature extraction unit 107 extracts a feature amount such as a size of the shape and information about which criterion was applied in which order in the past from CAD data and the process indicating a design process, among the past subject information 003. Then, as described above, the setting unit 101 creates the correspondence table 001 using this feature amount. Here, the correspondence table 001 includes the priority for each criterion of the past subject.

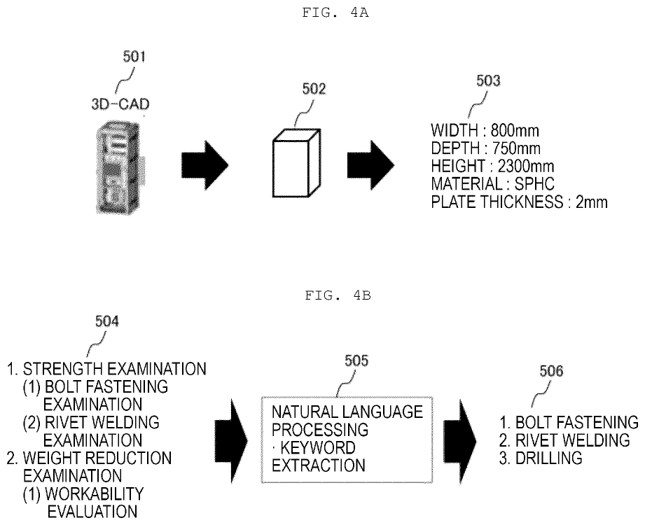

Next, a flow of processing by the design support device 10 according to this embodiment will be described using FIG. 3.

First, in step S101, the setting unit 101 reads the past subject information 003 in order to create the correspondence table 001.

Further, in step S102, the feature extraction unit 107 extracts the feature amount including shape information such as dimensions of a designed product and order of the criteria from the read 3D-CAD and the process of the past subject information 003.

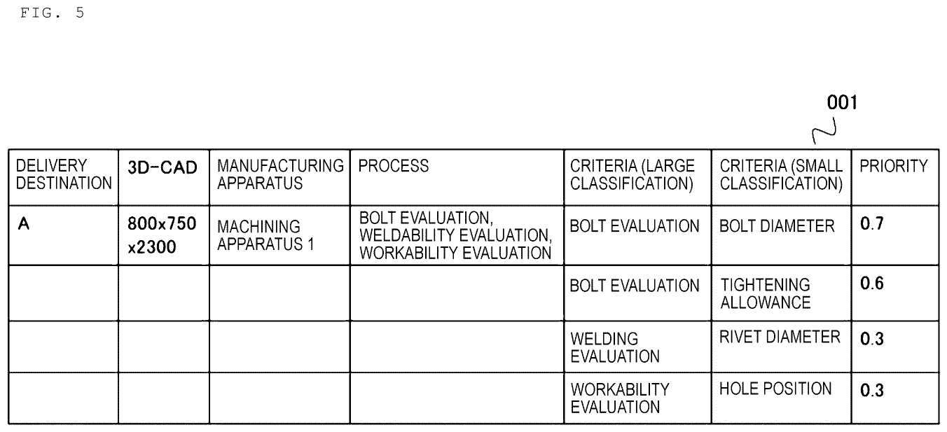

Here, details of an example of step S102 will be described. In step S102, FIG. 4 is an example of processing for extracting the feature amount from 3D-CAD, which is design information, and the process among the subject information. First, FIG. 4A is an example of extracting the feature amount from 3D-CAD. In FIG. 4A, the feature extraction unit 107 virtually prepares a boundary box 502 for a 3D-CAD 501 from points near and far from the origin. Then, the feature extraction unit 107 extracts a feature amount 503 related to 3D-CAD, such as shape information such as a width, depth, height, and plate thickness of the product, and material, using the boundary box 502. The feature amount related to the shape information can be prepared as numerical data.

Further, FIG. 4B is an example of extracting the feature amount from the process. In FIG. 4B, the feature extraction unit 107 executes natural language processing 505 such as morphological analysis when a process 504 is defined as a task. As a result, the feature extraction unit 107 extracts an order 506 of the criteria indicating the criteria and a check order of the criteria by keyword extraction. In the example illustrated in FIG. 4B, it is shown that when examining the strength, in the process 504, a bolt fastening portion and the strength of rivet welding are evaluated, and then weight reduction is examined. Therefore, the feature extraction unit 107 extracts the order 506 of the criteria, which is the order of 1. bolt fastening, 2. rivet welding, and 3. drilling, as a feature amount.

Next, in step S103, the setting unit 101 creates the correspondence table 001 based on the read past subject information 003 and the extracted feature amount. In other words, the past subject information 003 of the delivery destination, 3D-CAD, which is design information including product dimensions, manufacturing apparatus, and the process indicating the check procedure and the criteria, which are the check items performed for these items, are associated with each other. Specifically, the setting unit 101 sets the criterion, which is applied for the delivery destination, the 3D-CAD which is design information including dimensions, the manufacturing apparatus, and the process indicating the check procedure, and its priority. As a result, the setting unit 101 can create the correspondence table 001 illustrated in FIG. 5. As illustrated in FIG. 5, in the correspondence table 001, the criteria to be applied to the delivery destination, 3D-CAD including product dimensions, the manufacturing apparatus, and the process are classified, and the priority in the range of 0 to 1 is set for each small classification. For example, the priority of the criteria to be applied is set by referring to a size of the device designed for the delivery destination A and the process of examining the bolt fastening portion, welding portion, and drilling as points to be careful when manufacturing.

When the correspondence table 001 is created for the first time, a configuration in which the user of the design support device 10 manually inputs the priority may be adopted. This work can be carried out, for example, at the start of operation of the design support device 10. Thus, the correspondence table 001 may be created in advance and stored in the correspondence table DB D001.

Hereinafter, processing for presenting the criterion for the new subject will be described. In step S104, the input unit receives new subject information from a user. For this purpose, an input screen is displayed on the screen 103, and the user performs input work by using the input screen. The new subject information preferably has items similar to those of the past subject information 003, but it is sufficient that at least one of those items is included. In this embodiment, the new subject information includes the delivery destination, the 3D-CAD, the manufacturing apparatus, and the process.

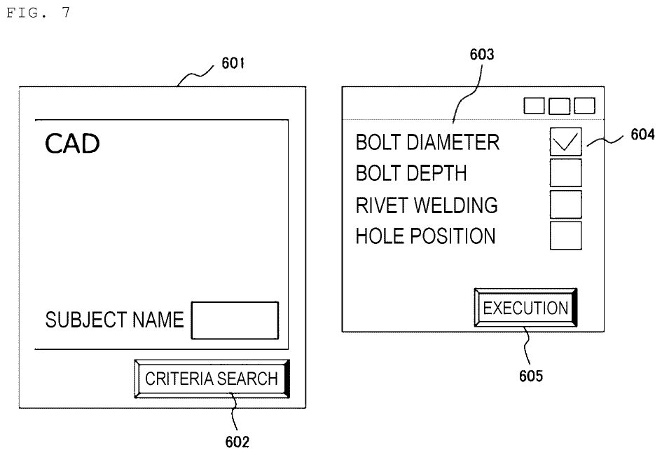

Next, in step S105, the priority calculation unit 104 calculates the priority using the correspondence table 001, and specifies an order of the criteria based on the calculated priority. A specific example of step S105 will now be described using FIG. 6. In this example, the priority calculation unit 104 executes rank learning processing to execute these pieces of processing. In FIG. 6, the priority calculation unit 104 receives the delivery destination, the CAD, the manufacturing apparatus, and the process as the new subject information 301. Then, the priority calculation unit 104 specifies an order 303 of the criteria to be preferentially applied, by using rank learning processing 302 using a model trained with data of the correspondence table 001. The rank learning processing 302 can be realized by a so-called computer program.

Here, priority calculation may be performed as follows. The priority calculation unit 104 specifies a record of the correspondence table 001 corresponding to the new subject information. In this case, it is desirable that a plurality of records is specified. Then, the priority calculation unit 104 calculates the priority of the new subject information based on the priority of the specified record.

Here, for specifying the record, a method of vectorizing a degree of similarity between the new subject information and the corresponding past subject information included in the corresponding correspondence table 001 and calculating the total sum of respective items, or a method of learning a relationship between a past subject and the priority of the criterion using machine learning and making inference for the new subject is included.

That is, in step S105, the priority calculation unit 104 specifies the record of the correspondence table 001 based on an index indicating relevance such as the degree of similarity.

Then, the priority calculation unit 104 converts the priority of the specified record using the index, and calculates the priority. More specifically, the weaker the relevance, the greater the change in the specified priority. Further, when the new subject information and the specified record completely match, it is desirable to use the specified priority as it is.

Next, in step S106, the output unit 106 presents the criteria in the order 303 on the screen 103. In this case, on the screen 103, the criteria satisfying the conditions such as the priority being equal to or higher than a preset threshold and a predetermined number of subjects from the top are displayed. Although the processing may be ended at this step, in this embodiment, processing of step S107 and subsequent steps below is executed.

In step S107, the input unit determines whether there is a selection for the presented criteria. Specifically, the input unit determines whether there is a selection of a criterion to be checked interactively from the user. As a result, if there is the selection (y), the processing proceeds to step S108. If there is no selection (n), the processing is ended.

Here, the display contents of the screen 103 in steps S106 and S107 will be described. FIG. 7 is an example of the display contents that present the shape to be checked and the criteria to be applied in descending order of priority on the screen 103. The reference numeral 601 indicates display contents for displaying design information (CAD) of the new subject and receiving input of a new subject name or the delivery destination. For this display, when the user presses a button 602 for searching for the criteria, the criteria 603 are displayed in descending order of priority on the screen 103. When the user selects the criterion 604 to be executed and presses an execution button 605, the shape check unit 105 performs shape check (step S108) using the criterion selected by the user.

Next, in step S108, the shape check unit 105 checks the selected criterion using criterion information 002 of the criterion DB D002. Here, the criterion information is information in which an allowable range for the item is associated with each criterion (small classification). Therefore, the shape check unit 105 realizes the check by determining whether the new subject information is included in the allowable range. This check includes the shape of the product, but may be performed from other viewpoints such as the strength and material. Then, in step S109, the output unit 106 outputs the selected criterion and the check result to the screen 103.

Further, in step S110, the update unit 102 records the selected criterion as a log.

Then, the update unit 102 updates the priority in the correspondence table 001 according to the selected criterion. For example, the priority of the selected criterion is increased. Further, among the criteria presented in step S106, a numerical value of the non-selected priority may be lowered. These priority changes include changing by a predetermined numerical value and replacing a numerical value and order with those of other priorities. Furthermore, similar to step S105, the priority may be changed using the rank learning processing 302 as illustrated in FIG. 6.

According to this embodiment, the object thereof is to create a program that can check manufacturability at the design stage. Further, in this case, by correlating the criteria and examination items to be checked with the design deliverables and subjects, omission of check items to be prioritized can be prevented. In addition, the present invention is not limited to this embodiment, and includes various modifications. For example, in the design support device 10, the check processing of S108 may be executed in real time in the background of design processing.

### REFERENCE SIGNS LIST

10: design support device
101: setting unit
102: update unit
103: screen
104: priority calculation unit
105: shape check unit
106: output unit
107: feature extraction unit
D001: correspondence table DB
D002: criterion DB
D003: past subject information DB

1. A design support device for performing a check of a defect in design, comprising:
a storage unit that stores a correspondence table in which past subject information for a product designed in the past is associated with a criterion indicating a check item;
an input unit that receives input of new subject information of a product of a new subject to be checked;
a priority calculation unit that calculates a priority of the criterion indicating the check item for the product of the new subject corresponding to the input new subject information, using the correspondence table; and
an output unit that outputs the calculated criterion according to the priority.

2. The design support device according to claim 1, wherein
the past subject information includes a delivery destination of the product, design information, a manufacturing apparatus, and a process of the check.

3. The design support device according to claim 2, further comprising:
a feature extraction unit that extracts a feature amount of the design information and the process; and
a setting unit that creates the correspondence table using the feature amount and the past subject information.

4. The design support device according to claim 3, wherein
the feature extraction unit extracts a shape, material, and strength of the product based on the design information and an order of the criteria based on the process, as the feature amount.

5. The design support device according to claim 1, further comprising:
a shape check unit that executes a check of the product of the new subject according to the designation from a user for the output criterion.

6. A design support method using a design support device for performing a check of a defect in design, comprising:
storing, in a storage unit, a correspondence table in which past subject information for a product designed in the past is associated with a criterion indicating a check item;
receiving, by an input unit, input of new subject information of a product of a new subject to be checked;
calculating, by a priority calculation unit, a priority of the criterion indicating the check item for the product of the new subject corresponding to the input new subject information, using the correspondence table; and
outputting, by an output unit, the calculated criterion according to the priority.

7. The design support method according to claim 6, wherein
the past subject information includes a delivery destination of the product, design information, a manufacturing apparatus, and a process of the check.

8. The design support method according to claim 7, further comprising:
extracting, by a feature extraction unit, a feature amount of the design information and the process; and
creating, by a setting unit, the correspondence table using the feature amount and the past subject information.

9. The design support method according to claim 8, comprising:
extracting, by the feature extraction unit, a shape, material, and strength of the product based on the design information and an order of the criteria based on the process, as the feature amount.

10. The design support method according to claim 6, further comprising:
executing, by a shape check unit, a check of the product of the new subject according to the designation from a user for the output criterion.

11. A storage medium storing program for causing a design support device for performing a check of a defect in design to function as a computer,
wherein the program causes the design support device to function as
a storage unit that stores a correspondence table in which past subject information for a product designed in the past is associated with a criterion indicating a check item,
an input unit that receives input of new subject information of a product of a new subject to be checked,
a priority calculation unit that calculates a priority of the criterion indicating the check item for the product of the new subject corresponding to the input new subject information, using the correspondence table, and
an output unit that outputs the calculated criterion according to the priority.

12. The storage medium according to claim 11, wherein
the past subject information includes a delivery destination of the product, design information, a manufacturing apparatus, and a process of the check.

13. The storage medium according to claim 12, wherein
the program further causes the design support device to function as
a feature extraction unit that extracts a feature amount of the design information and the process, and
a setting unit that creates the correspondence table using the feature amount and the past subject information.

14. The storage medium according to claim 13, wherein
the program causes the feature extraction unit to extract a shape, material, and strength of the product based on the design information and an order of the criteria based on the process as the feature amount.

15. The storage medium according to any one of claims 11 to 14, wherein
the program further causes the design support device to function as a shape check unit that executes a check of the product of the new subject according to the designation from a user for the output criterion.
